(19) United States
(12) Patent Application Publication
(10) Pub. No.: US 2011/0265839 A1
(43) Pub. Date: Nov. 3, 2011

(54) THERMOELECTRIC CONVERSION MODULE

(75) Inventor: Yuichi Hiroyama, Ibaraki (JP)

(73) Assignee: SUMITOMO CHEMICAL COMPANY, LIMITED, Chuo-ku, Tokyo (JP)

(21) Appl. No.: 13/143,364

(22) PCT Filed: Jan. 8, 2010
(86) PCT No.: PCT/JP2010/050162

§ 371 Date: Jul. 6, 2011

(30) Foreign Application Priority Data
Jan. 15, 2009 (JP) 2009-006668

(51) Int. Cl. H01L 35/32

(52) U.S. Cl. 136/224

(57) ABSTRACT

A thermoelectric conversion module is provided with a p-type thermoelectric conversion element and an n-type thermoelectric conversion element; a support frame having a through hole with the p-type thermoelectric conversion element therein and a through hole with the n-type thermoelectric conversion element therein; and an electrode electrically connecting the p-type thermoelectric conversion element with the n-type thermoelectric conversion element; at least one element of the p-type thermoelectric conversion element and the n-type thermoelectric conversion element has a shape having a vertex and/or an edge; the at least one element has been secured to the support frame by an adhesive adhering to a region of the surface of the at least one element except for the vertex and the edge and to the support frame.

### TECHNICAL FIELD

The present invention relates to a thermoelectric conversion module.

### BACKGROUND ART

There is a known thermoelectric conversion module having a structure wherein thermoelectric conversion elements are inserted in through holes of a support frame and wherein entire side faces including edges of the thermoelectric conversion elements are bonded to the support frame by an inorganic adhesive.

### Citation List

### Patent Literature

Patent Literature 1: JP10-321921A

### SUMMARY OF INVENTION

### Technical Problem

However, the conventional structure had a problem that the vertices and edges of the thermoelectric conversion elements were likely to break because of stress produced in a high-temperature environment, so as to cause degradation of performance of the thermoelectric conversion module in temperature cycles.

It is therefore an object of the present invention to provide a thermoelectric conversion module in which the vertices and edges of the thermoelectric conversion elements are unlikely to break, so as to suppress the degradation of performance in temperature cycles.

### Solution to Problem

The present invention provides a thermoelectric conversion module comprising: a p-type thermoelectric conversion element and an n-type thermoelectric conversion element; a support frame having a through hole with the p-type thermoelectric conversion element therein and a through hole with the n-type thermoelectric conversion element therein; and an electrode electrically connecting the p-type thermoelectric conversion element with the n-type thermoelectric conversion element, wherein at least one element of the p-type thermoelectric conversion element and the n-type thermoelectric conversion element has a shape having a vertex and/or an edge, and wherein at least one element mentioned above has been secured to the support frame by an adhesive adhering to a region of the surface of the at least one element except for the vertex and the edge and to the support frame.

In the thermoelectric conversion module of the present invention, the vertex and the edge of the thermoelectric conversion element are not directly secured to the support frame by the adhesive and, therefore, thermal stress on the vertex and the edge of the thermoelectric conversion element is relaxed, so as to prevent the degradation of performance of the thermoelectric conversion module in temperature cycles.

It is preferable that the shape of the p-type thermoelectric conversion element and the n-type thermoelectric conversion element be a prism and an axis of the prism be parallel to an axis of the through hole. By employing the prism in this arrangement, it is feasible to efficiently arrange a large number of thermoelectric conversion elements in a small space.

### ADVANTAGEOUS EFFECTS OF INVENTION

The present invention successfully provides the thermoelectric conversion module wherein the vertices and the edges of the thermoelectric conversion elements are unlikely to break, so as to suppress the degradation of performance.

### BRIEF DESCRIPTION OF DRAWINGS

FIG. 1 is a perspective view showing a thermoelectric conversion module which is an embodiment of the present invention.

FIG. 2 is top plan views showing joining states between a thermoelectric conversion element and a support frame according to the present invention.

### DESCRIPTION OF EMBODIMENTS

The preferred embodiments of the present invention will be described below in detail with reference to the accompanying drawings. In the description of the drawings, identical or equivalent elements will be denoted by the same reference signs, without redundant description. It is also noted that dimensional ratios in each drawing do not always coincide with actual dimensional ratios.

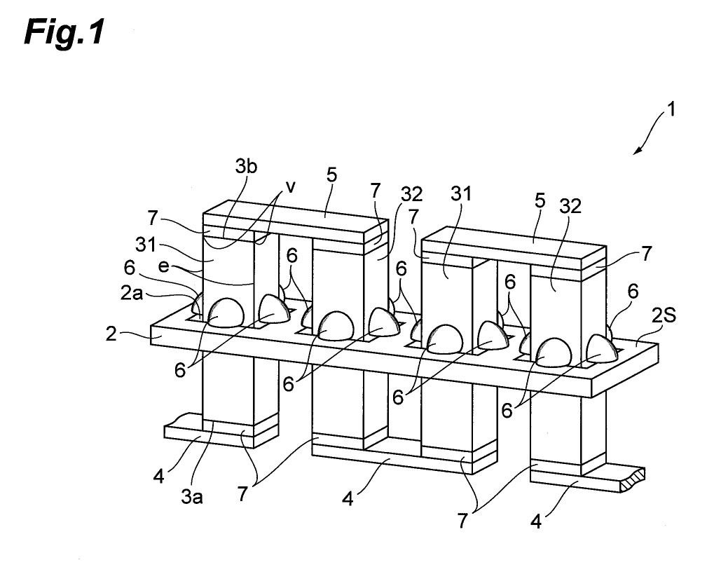

FIG. 1 is a perspective view showing the appearance of thermoelectric conversion module 1 which is an embodiment of the present invention. As shown in FIG. 1, the thermoelectric conversion module 1 is provided with a support frame 2, p-type thermoelectric conversion elements 31, n-type thermoelectric conversion elements 32, first electrodes 4, and second electrodes 5. It is assumed herein that the thermoelectric conversion module 1 is used with the first electrode 4 side being set as a relatively low temperature side and with the second electrode 5 side being set as a relatively high temperature side.

The p-type thermoelectric conversion elements 31 and n-type thermoelectric conversion elements 32 have a quadrangular prism shape. The shape of these elements is preferably a rectangular prism shape the both end faces of which are rectangular and is more preferably a square prism shape the both end faces of which are square.

While there are no particular restrictions on a material of the p-type thermoelectric conversion elements 31, examples of the material include: mixed metal oxides such as NaₓCoO₂ (0<x<1) and Ca₃Co₄O₉; silicides such as MnSi_{1.73}, Fe₁₋ₓMnₓSi₂, Si_{0.8}Ge_{0.2}:B (B-doped Si_{0.8}Ge_{0.2}), and β-FeSi₂; skutterudites such as CoSb₃, FeSb₃, and RFe₃CoSb₁₂ (where R represents La, Ce, or Yb); Te-containing alloys such as BiTeSb, PbTeSb, Bi₂Te₃, PbTe, Sb₂Te₃; and Zn₄Sb₃.

While there are no particular restrictions on a material of the n-type thermoelectric conversion elements 32, examples of the material include: mixed metal oxides such as SrTiO₃, Zn₁₋ₓAlₓO, CaMnO₃, LaNiO₃, BaTiO₃, and Ti₁₋ₓNbₓO; silicides such as Mg₂Si, Fe₁₋ₓCoₓSi₂, Si_{0.8}Ge_{0.2}:P (P-doped Si_{0.8}Ge_{0.2}), and β-FeSi₂; skutterudites such as CoSb₃; clathrate compounds such as Ba₈Al₁₂Si₃₀, Ba₈AlₓSi₄₆₋ₓ, Ba₈Al₁₂Ge₃₀, and Ba₈GaₓGe₄₆₋ₓ; boron compounds such as CaB₆, SrB₆, BaB₆, and CeB₆; Te-containing alloys such as BiTeSb, PbTeSb, Bi₂Te₃, PbTe, and Sb₂Te₃; and Zn₄Sb₃.

Since the thermoelectric conversion elements using these materials exhibit high thermoelectric characteristics, particularly, at about 700 to 800° C., the thermoelectric conversion module using the thermoelectric conversion elements of such materials is suitably applicable, particularly, to power generating apparatus employing a high-temperature heat source. For example, a particularly preferred use range is approximately 300 to 570 K for the BiTe type materials; 300 to 850 K for the PbTe type materials; 500 to 800 K for the silicide type materials such as MnSi and MgSi; 500 to 750 K for the ZnSb type materials; 300 to 900 K for the CoSb (skutterudite) type materials; 500 to 1100 K for the oxide type materials.

Among these materials, in terms of manufacturing cost and stability in the atmosphere, it is preferable to adopt the thermoelectric conversion elements made of the mixed metal oxides and it is particularly preferable to adopt a combination of Ca₃Co₄O₉ as a material of the p-type thermoelectric conversion elements and CaMnO₃ as a material of the n-type thermoelectric conversion elements.

The support frame 2 supports and holds the p-type thermoelectric conversion elements 31 and the n-type thermoelectric conversion elements 32. The support frame 2 preferably has a thermal insulation property and preferably also has an electrical insulation property. In the present embodiment, the support frame 2 has a platelike shape and through holes 2a are formed in respective positions where the p-type thermoelectric conversion elements 31 and the n-type thermoelectric conversion elements 32 are to be inserted into. While there are no particular restrictions on the shape of the through holes 2a, the through holes 2a preferably have the shape corresponding to the cross-sectional shape of the p-type thermoelectric conversion elements 31 and the n-type thermoelectric conversion elements 32; for example, in cases where the cross-sectional shape of each of the thermoelectric conversion elements 31, 32 is quadrangular, the through holes 2a preferably also have a quadrangular shape.

While there are no particular restrictions on a material of this support frame 2, a ceramic material, for example, can be used. A preferred ceramic material is an oxide with high electrical and thermal insulation properties and examples of such oxides include zirconia, cordierite, alumina, mullite, magnesia, silica, and calcia. These oxides can be used singly or in combination of two or more. The ceramic material can contain glass frit on an as-needed basis.

The p-type thermoelectric conversion element 31 or the n-type thermoelectric conversion element 32 is inserted and secured in each through hole 2a of the support frame 2, and the p-type thermoelectric conversion elements 31 and the n-type thermoelectric conversion elements 32 are alternately arranged along a row of the through holes 2a. In the present embodiment, particularly, the elements are arranged in the respective through holes 2a so that axes of the quadrangular prisms of the p-type thermoelectric conversion elements 31 and the n-type thermoelectric conversion elements 32 are substantially parallel to axes of the through holes 2a.

Each of the thermoelectric conversion elements 31 and 32 is secured to the support frame 2 by adhesive 6 adhering to regions of side faces of each of the thermoelectric conversion elements 31, 32 except for vertices v and edges e and to the support frame 2. Namely, the adhesive 6 is out of contact with the vertices v and edges e in the side faces of each of the thermoelectric conversion elements 31, 32. More specifically, in the present embodiment, the support frame 2 is secured to the regions of the four side faces of the p-type thermoelectric conversion elements 31 and n-type thermoelectric conversion elements 32 except for the respective vertices v and edges e, by the adhesive 6. The adhesive 6 does not adhere to interior surfaces of the through holes 2a of the support frame 2 but adheres to a principal surface 2S outside the through holes 2a in the support frame 2.

While there are no particular restrictions on the adhesive 6, the adhesive 6 can be a resin-based adhesive and it is preferable to use an inorganic-based adhesive in order to enhance durability at high temperatures. Examples of the inorganic-based adhesives include inorganic-based adhesives containing silica-alumina, silica, zirconia, or alumina as a major ingredient (e.g., SUMICERAM-S (trade name available from ASAHI Chemical Co., Ltd.)), and inorganic-based adhesives containing zirconia-silica as a major ingredient (e.g., Aron Ceramics (trade name available from TOAGOSEI CO., LTD.)). When any of these inorganic-based adhesives is used, the adhesive can be applied and dried, and thereafter heated at about 100 to 200° C.

Each first electrode 4 is an electrode that electrically connects one end faces 3a of p-type thermoelectric conversion element 31 and n-type thermoelectric conversion element 32 adjacent to each other. While there are no particular restrictions on a material of the first electrodes 4 as long as it has an electrically conductive property, in terms of improvement in heat resistance, corrosion resistance, and adhesion of the electrodes to the thermoelectric elements, a preferred material is a metal containing, as a major ingredient, at least one element selected from the group consisting of titanium, vanadium, chromium, manganese, iron, cobalt, nickel, copper, molybdenum, silver, palladium, gold, tungsten, platinum, and aluminum. The major ingredient herein refers to an ingredient contained 50% by volume or more in the electrode material.

Each second electrode 5 is an electrode that electrically connects the other end faces 3b of p-type thermoelectric conversion element 31 and n-type thermoelectric conversion element 32 adjacent to each other. A material of the second electrodes 5 can be the same as that of the first electrodes 4. All the p-type thermoelectric conversion elements 31 and the n-type thermoelectric conversion elements 32 are alternately and electrically serially connected by the second electrodes 5 and the first electrodes 4.

As shown in FIG. 1, the p-type thermoelectric conversion elements 31 and the n-type thermoelectric conversion elements 32 are preferably secured to the first electrodes 4 and the second electrodes 5, through a joint material 7 of a solder such as AuSb and PbSb, or a silver paste. This joint material 7 is preferably one which stays solid during use as the thermoelectric conversion module. A metallization layer can be formed on a surface of each of the thermoelectric conversion elements 31, 32 to be bonded to the electrode.

In the thermoelectric conversion module of the present embodiment as described above, since the vertices v and edges e of the thermoelectric conversion elements 31, 32 are not directly secured to the support frame 2, thermal stress on these vertices v and edges e is relaxed, so as to prevent degradation of performance of the thermoelectric conversion module in temperature cycles.

The present invention is not limited only to the above embodiment but can be modified in various ways.

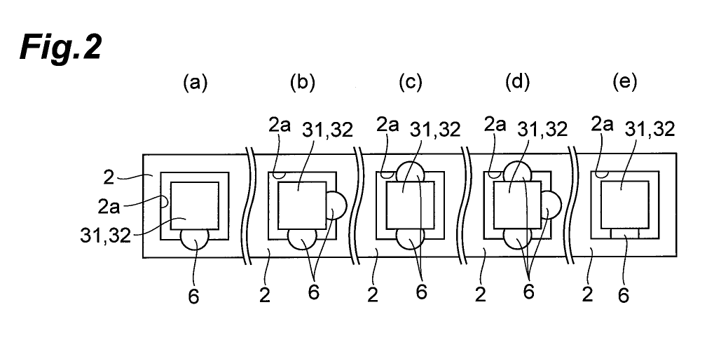

For example, in the example of FIG. 1, the adhesive 6 adheres to all the four side faces of the p-type thermoelectric conversion elements 31 and the n-type thermoelectric conversion elements 32, but the adhesive 6 does not always have to adhere to all of the side faces. For example, as shown in FIG. 2 (a) to (d) which is top plan views showing secured states of the p-type thermoelectric conversion element 31 or the n-type thermoelectric conversion element 32 to the support frame 2, the adhesive 6 can adhere to any number of side faces excluding four. For example, the adhesive 6 can be applied on only one side face as in FIG. 2 (a); the adhesive 6 can be applied on only two adjacent side faces as in FIG. 2 (b); the adhesive 6 can be applied on only two opposing side faces as in FIG. 2 (c); the adhesive 6 can be applied on only three side faces as in FIG. 2 (d).

While in the above embodiment the adhesive 6 adheres to the principal surface 2S of the support frame 2, without having to be limited to this, the adhesive 6 can adhere anywhere on the support frame 2; for example, the adhesive 6 can adhere to an interior surface of the through hole 2a, as shown in FIG. 2 (e).

While in the above embodiment the p-type thermoelectric conversion elements 31 and the n-type thermoelectric conversion elements 32 have the quadrangular prism shape in order to efficiently arrange a large number of thermoelectric conversion elements in a small space, the thermoelectric conversion elements can have any other prism shape with vertices and edges, like triangular, hexagonal, octagonal, and others, or can have a cylindrical shape with edges but without vertices, like a circular cylinder, or can have an irregular shape with vertices and/or edges. In these cases, the present invention can also be carried out as long as the adhesive 6 adheres to any part except for the vertices and/or edges in surfaces of the thermoelectric conversion elements and to the support body 2.

While in the above embodiment all the p-type thermoelectric conversion elements 31 and the n-type thermoelectric conversion elements 32 are secured to the support frame 2 by the adhesive 6 which adheres to the regions of their surfaces except for the vertices v and edges e and to the support frame 2, the present invention can also be carried out in a configuration wherein only arbitrary one of the p-type thermoelectric conversion elements 31 and the n-type thermoelectric conversion elements 32 is fixed by the aforementioned adhesive 6.

While it is also noted that the shape and arrangement of the through holes 2a are not limited only to those in the above embodiment, the through holes 2a can also be arranged in a matrix pattern, for example.

### LIST OF REFERENCE SIGNS

1 thermoelectric conversion module; 2 support frame; 2a through holes; 2S principal surface; 31 p-type thermoelectric conversion elements; 32 n-type thermoelectric conversion elements; 4 first electrodes; 5 second electrodes; 6 adhesive; 7 joint material.

1. A thermoelectric conversion module comprising:
a p-type thermoelectric conversion element and an n-type thermoelectric conversion element;
a support frame having a through hole with the p-type thermoelectric conversion element therein and a through hole with the n-type thermoelectric conversion element therein; and
an electrode electrically connecting the p-type thermoelectric conversion element with the n-type thermoelectric conversion element,
wherein at least one element of the p-type thermoelectric conversion element and the n-type thermoelectric conversion element has a shape having a vertex and/or an edge, and
wherein said at least one element has been secured to the support frame by an adhesive adhering to a region of the surface of the at least one element except for the vertex and the edge and to the support frame.

2. The thermoelectric conversion module according to claim 1, wherein the shape of said at least one element is a prism and an axis of the prism is parallel to an axis of the through hole.
